(19) United States
(12) Patent Application Publication
(10) Pub. No.: US 2015/0048469 A1
(43) Pub. Date: Feb. 19, 2015

(54) IMAGE SENSOR

(71) Applicant: Young-Woo JUNG, Yongin-si (KR)

(72) Inventor: Young-Woo JUNG, Yongin-si (KR)

(21) Appl. No.: 14/294,827

(22) Filed: Jun. 3, 2014

(30) Foreign Application Priority Data
Aug. 19, 2013 (KR) 10-2013-0098067

(51) Int. Cl. H01L 31/0216; H01L 31/0232

(52) U.S. Cl. CPC H01L 31/02161; H01L 31/02162; H01L 31/02327
USPC 257/432

(57) ABSTRACT

An image sensor is provided. The image sensor comprises a substrate including a first surface and a second surface which are opposite to the first surface and a photoelectric converting element formed therein, a graphene layer formed on the first surface of the substrate to be flat, and a plurality of micro lenses which is formed on the graphene layer.

### CROSS-REFERENCE TO RELATED APPLICATION

This application claims priority from Korean Patent Application No. 10-2013-0098067 filed on Aug. 19, 2013 in the Korean Intellectual Property Office, and all the benefits accruing therefrom under 35 U.S.C. 119, the contents of which in its entirety are herein incorporated by reference.

### TECHNICAL FIELD

Example embodiments relate to an image sensor. More specifically, at least one example embodiment relates to an image sensor including a graphene or graphyne layer having a plurality of micro lenses.

### BACKGROUND

An image sensor is a device which converts an optical image into an electrical signal. Recently, as the computer industry and the communication industry have developed, demand for an image sensor with an improved performance has increased in various fields such as digital cameras, camcorders, personal communication systems (PCS), game devices, security cameras, medical micro cameras, and robots.

### SUMMARY

Example embodiments are provided in an effort to provide an image sensor which uses a graphene layer to improve a signal to noise ratio while maintaining an anti-moisture absorption function.

Technical problems solved by at least one example embodiment are not limited to the above-mentioned technical problems, and other technical problems, which are not mentioned above, can be clearly understood by those skilled in the art from the following descriptions.

In one example embodiment, there is provided an image sensor comprising a substrate including a first surface and a second surface which are opposite to the first surface and a photoelectric converting element formed therein, a graphene layer formed on the first surface of the substrate to be flat, and a plurality of micro lenses formed on the graphene layer.

The image sensor may further comprise an insulating structure including a metal wiring line on the second surface of the substrate, and a color filter disposed between the first surface of the substrate and the microlens. In addition, the graphene layer is disposed between the color filter and the first surface of the substrate.

The graphene layer may be formed to be in contact with the first surface of the substrate.

The image sensor may further comprise a first oxide insulating layer between the graphene layer and the first surface of the substrate.

The first oxide insulating layer is in contact with the graphene layer.

The graphene layer and the metal wiring line are electrically connected with each other through a through via which penetrates the substrate.

The image sensor may further comprise an insulating structure including a metal wiring line on the second surface of the substrate, and a color filter disposed between the first surface of the substrate and the microlens. In addition, the graphene layer may be disposed between the color filter and the microlens.

The image sensor may further comprise an insulating structure including a metal wiring line, between the first surface of the substrate and the graphene layer.

The image sensor may further comprise a color filter between the insulating structure and the microlens, and the graphene layer is disposed between the color filter and the insulating structure.

The image sensor may further comprise a color filter between the first surface of the substrate and the microlens, and the graphene layer is disposed between the color filter and the microlens.

The graphene layer may be a monolayer graphene.

The graphene layer may be a p-type graphene layer.

In another example embodiment, there is provided an image sensor comprising a substrate in which a sensing region, an Optical Black (OB) region, and a peripheral region are defined and which includes a photoelectric converting element therein, an insulating structure which is formed on a first surface of the substrate and includes a metal wiring line, a graphene layer which is formed on a second surface which is opposite to the first surface of the substrate and formed over the sensing region and the OB region to be flat, and a plurality of micro lenses formed on the graphene layer.

The graphene layer may be formed to be in contact with the second surface of the substrate.

The image sensor may further comprise an insulating layer between the graphene layer and the substrate to be in contact with the graphene layer.

The insulating layer may include HfOx.

The image sensor may further comprise an insulating layer between the graphene layer and the microlens to be in contact with the graphene layer.

The graphene layer may be electrically connected with the metal wiring line.

The graphene layer may be formed to extend to the peripheral region, and a landing pad formed on the graphene layer which is formed in the peripheral region, and a redistribution line which is electrically connected to the landing pad, are further provided.

The redistribution line and the metal wiring line may be connected through a through via.

In still another example embodiment, there is provided an image sensor comprising a substrate including a first surface and a second surface which are opposite to the first surface and a photoelectric converting element formed therein, an insulating structure on a first surface of the substrate which includes a metal wiring line, a graphene layer which is formed on the second surface of the substrate and is applied with a negative voltage, and a plurality of micro lenses which is formed on the graphene layer.

The graphene layer may be formed to be in contact with the second surface of the substrate.

The graphene layer may be electrically connected with the metal wiring line.

The metal wiring line and the graphene layer may be connected with each other through a through via which penetrates the substrate.

A hole concentration of the graphene layer may be adjusted by adjusting the negative voltage.

According to at least one example embodiment, an image sensor includes a substrate having a first region and a second region and including a first surface and a second surface opposite the first surface, the second surface including a photoelectric converting element, a carbon-based layer on the first surface extending over at least one of the first region and the second region, and a plurality of micro lenses on the carbon-based layer.

Other detailed matters of the example embodiments are included in the detailed description and the drawings.

### BRIEF DESCRIPTION OF THE DRAWINGS

The above and other features and advantages of the example embodiments will become more apparent by describing in detail example embodiments thereof with reference to the attached drawings in which:

FIG. 1 is a block diagram of an image sensor according to example embodiments;

FIG. 2 is an equivalent circuit diagram of a sensor array of FIG. 1;

FIG. 3 is a diagram illustrating an image sensor according to a first example embodiment;

FIG. 4 is a diagram illustrating an image sensor according to a second example embodiment;

FIG. 5 is a diagram illustrating an image sensor according to a third example embodiment;

FIG. 6 is a diagram illustrating an image sensor according to a fourth example embodiment;

FIG. 7 is a diagram illustrating an image sensor according to a fifth example embodiment;

FIG. 8 is a schematic diagram illustrating a conductivity change of a graphene in accordance with a voltage which is applied to a monolayer graphene in the monolayer graphene;

FIG. 9 is a diagram illustrating an image sensor according to an example sixth embodiment;

FIG. 10 is a diagram illustrating an image sensor according to a seventh example embodiment;

FIG. 11 is a block diagram illustrating an example in which an image sensor according to the example embodiments is applied to a digital camera;

FIG. 12 is a block diagram illustrating an example in which an image sensor according to example embodiments is applied to a computing system; and

FIG. 13 is a block diagram illustrating an example of an interface which is used for the computing system of FIG. 12.

### DETAILED DESCRIPTION

Advantages and features of the example embodiments and methods of accomplishing the same may be understood more readily by reference to the following detailed description of preferred example embodiments and the accompanying drawings. The example embodiments may, however, be embodied in many different forms and should not be construed as being limited to the example embodiments set forth herein. Rather, these example embodiments are provided so that this disclosure will be thorough and complete and will fully convey the concept of the example embodiments to those skilled in the art, and the example embodiments will only be defined by the appended claims. Like reference numerals refer to like elements throughout the specification.

The terminology used herein is for the purpose of describing particular example embodiments only and is not intended to be limiting of the example embodiments. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on”, “directly connected to” or “directly coupled to” another element or layer, there are no intervening elements or layers present. As used herein, the term “and/or” includes any and all combinations of one or more of the associated listed items.

It will be understood that, although the terms “first,” “second,” etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the example embodiments.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Examples embodiments are described herein with reference to cross-section illustrations that are schematic illustrations of idealized example embodiments (and intermediate structures). As such, variations from the shapes of the illustrations as a result, for example, of manufacturing techniques and/or tolerances, are to be expected. Thus, these example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the example embodiments.

Unless otherwise defined, all terms (including technical and scientific terms) used herein have the same meaning as commonly understood by one of ordinary skill in the art to which the example embodiments belong. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

In the drawing figures, the dimensions of layers and regions may be exaggerated for clarity of illustration. Like reference numerals refer to like elements throughout. The same reference numbers indicate the same components throughout the specification.

Reference will now be made in detail to example embodiments, examples of which are illustrated in the accompanying drawings. In this regard, the present example embodiments may have different forms and should not be construed as being limited to the descriptions set forth herein. Accordingly, the example embodiments are merely described below, by referring to the figures, to explain example embodiments of the present description.

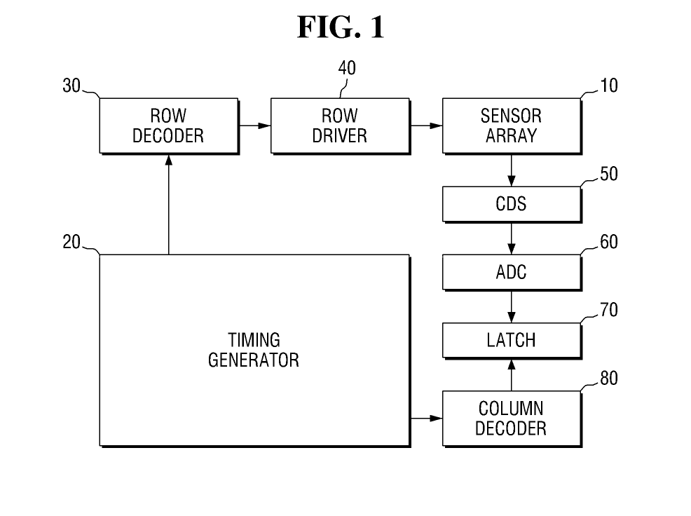

FIG. 1 is a block diagram of an image sensor according to example embodiments.

Referring to FIG. 1, an image sensor according to at least one example embodiment includes a sensor array 1 in which pixels including photoelectric converting elements are two-dimensionally arranged, a timing generator 20, a row decoder 30, a row driver 40, a correlated double sampler (CDS) 50, an analog to digital converter (ADC) 60, a latch 70, and a column decoder 80.

According to at least one example embodiment, the sensor array 10 includes a plurality of unit pixels which are two-dimensionally arranged. The plurality of unit pixels serves to convert an optical image into an electrical output signal. The sensor array 10 receives a plurality of driving signals such as a row selection signal, a reset signal, and a charge transmission signal from the row driver 40 to be driven. The converted electrical output signal is supplied to the correlated double sampler (CDS) 50 through a vertical signal line.

According to at least one example embodiment, the timing generator 20 supplies a timing signal and a control signal to the row decoder 30 and the column decoder 80.

According to at least one example embodiment, the row driver 40 supplies a plurality of driving signals, which drives the plurality of unit pixels in accordance with a decoding result in the row decoder 30, to an active pixel sensor array 10. Generally, when the unit pixels are arranged in a matrix, the driving signal is supplied for every row.

According to at least one example embodiment, the correlated double sampler 50 receives the output signal, which is formed in the active pixel sensor array 10 through the vertical signal line, to hold and sample the output signal. That is, a specific noise level and a signal level by the output signal are double-sampled to output a difference level corresponding to a difference between the noise level and the signal level.

According to at least one example embodiment, the analog to digital converter 60 converts an analog signal corresponding to the difference level into a digital signal and outputs the digital signal.

According to at least one example embodiment, the latch 70 latches the digital signals, and the latched signals are sequentially output to an image signal processing unit (not illustrated in the drawing) in accordance with a decoding result in the column decoder 80.

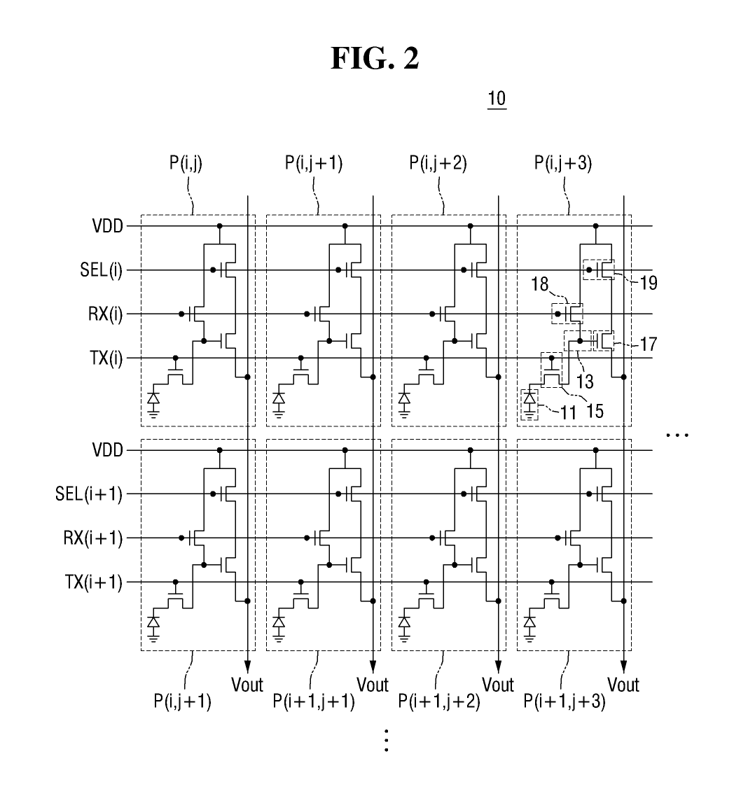

FIG. 2 is an equivalent circuit diagram of a sensor array of FIG. 1, according to at least one example embodiment.

Referring to FIG. 2, pixels P are arranged in a matrix to configure the sensor array 10. Each pixel P includes a photoelectric converting element 11, a floating diffusion region 13, a charge transmitting element 15, a drive element 17, a reset element 18, and a selecting element 19. Functions of those elements will be described with i-th row pixels P(i, j), P(i, j+1), P(i, j+2), P(i, j+3), . . . , as an example.

According to at least one example embodiment, the photoelectric converting element 11 absorbs incident light to store a charge corresponding to light quantity. As the photoelectric converting element 11, a photo diode, a photo transistor, a photo gate, a pinned photo diode, or a combination thereof may be alternatively used, and a photo diode is illustrated in the drawing as an example.

According to at least one example embodiment, each photoelectric converting element 11 is coupled to each of the charge transmitting elements 15 which transmits stored charges to the floating diffusion region 13. The floating diffusion region FD 13 is a region in which a charge is converted into a voltage and a parasitic capacitance is provided therein so that the charges are cumulatively stored.

According to at least one example embodiment, the drive element 17 which is exemplified as a source follower amplifier amplifies a change of an electric potential of the floating diffusion region 13 which receives the charge stored in each of the photoelectric converting element 11 and outputs the amplified change to an output line Vout.

According to at least one example embodiment, the reset element 18 periodically resets the floating diffusion region 13. The reset element 18 may include one MOS transistor which is driven by a bias which is supplied by a reset line RX(i) which applies a predetermined bias (that is, a reset signal). When the reset element 18 is turned on by the bias which is supplied by the reset line RX(i), a predetermined electric potential which is supplied to a drain of the reset element 18, for example, a power voltage VDD is transmitted to the floating diffusion region 13.

According to at least one example embodiment, the selecting element 19 is configured to select a pixel P which is read out in the unit of row. The selecting element 19 may include one MOS transistor which is driven by a bias (that is, a row selection signal) which is supplied by a row selecting line SEL(i). When the selecting element 19 is turned on by the bias which is supplied by the row selection line SEL(i), a predetermined electric potential which is supplied to a drain of the selecting element 19, for example, a power voltage VDD is transmitted to a drain region of the drive element 17.

According to at least one example embodiment, a transmission line TX(i) which applies a bias to the charge transmitting element 15, the reset line RX(i) which applies a bias to the reset element 18, and the row selection line SEL(i) which applies a bias to the selecting element 19, may be arranged so as to extend substantially in parallel to each other in a row direction.

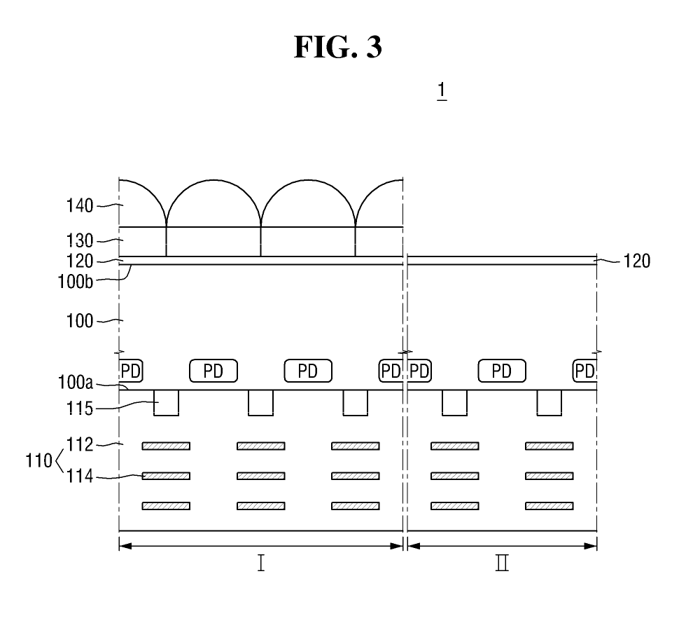

An image sensor according to the first example embodiment will be described with reference to FIG. 3.

FIG. 3 is a diagram illustrating an image sensor according to a first example embodiment.

Referring to FIG. 3, an image sensor 1 according to the first example embodiment may include a first region I and a second region II. The image sensor 1 includes an insulating structure 110 and a graphene layer 120 which are formed in the first region I and the second region II. Further, the image sensor 1 may include a color filter 130 and a plurality of micro lenses 140 which are formed in the first region I.

According to at least one example embodiment, the first region I is a sensing region and the second region II may be an OB region which is an optical black region. The first region I and the second region II may be regions in which the sensing array 10 of FIG. 1 is formed.

According to at least one example embodiment, the second region II is a region in which light is blocked to provide a reference of a black signal to the first region I and has the same structure as the first region I but is formed to block the light from entering. Therefore, a dark current of the sensing array in the first region I is corrected based on a dark current of the second region II.

According to at least one example embodiment, a substrate 100 includes a first surface 100a and a second surface 100b which are opposite to each other. The first surface 100a of the substrate 100 may be a front side of the substrate 100 and the second surface 100b of the substrate may be a back side of the substrate 100. The substrate 100 may use a P-type or N-type bulk substrate or use a substrate obtained by growing a P-type or N-type epitaxial layer on a P-type bulk substrate or growing a P-type or N-type epitaxial layer on an N-type bulk substrate. Further, the substrate 100 may use a substrate such as an organic plastic substrate other than a semiconductor substrate.

According to at least one example embodiment, in the substrate 100, the first region I and the second region II, the photoelectric converting element, for example, a photo diode PD is formed. The photoelectric converting element PD may be formed so as to be close to the first surface 100a of the substrate, but is not limited thereto.

According to at least one example embodiment, a plurality of first gates 115 may be formed on the first surface 100a of the substrate. The first gate 115 may be, for example, a gate of the charge transmitting element, a gate of the reset element, or a gate of the drive element. In FIG. 3, the first gate 115 is formed on the first surface 100a of the substrate, but is not limited thereto and may be formed to be recessed in the substrate 100.

According to at least one example embodiment, the insulating structure 110 may be disposed above the first surface 100a. That is, the insulating structure 110 may be formed on a front side of the substrate 100. The insulating structure 110 may include an interlayer insulating layer 112 and a first metal wiring line 114. The interlayer insulating layer 112 may include at least one of a silicon oxide film, a silicon nitride film, a silicon oxynitride film, and a combination thereof, but is not limited thereto. The first metal wiring line 114 may include aluminum (Al), copper (Cu), or tungsten (W), but is not limited thereto.

According to at least one example embodiment, the first wiring line 114 may include a plurality of wiring lines formed in the first region I and in the second region II, and are sequentially laminated. In FIG. 1, the first metal wiring line 114 is formed of three layers which are sequentially laminated for the convenience of description, but is not limited thereto.

According to at least one example embodiment, the graphene layer 120 may be disposed above the second surface 100b of the substrate. That is, the graphene layer 120 may be formed on a back side of the substrate 100. The graphene layer 120 may be disposed over both the first region I and the second region II. Specifically, the graphene layer 120 may be formed in the entire first region I and second region II. The graphene layer 120 may be formed above the second surface 100b of the substrate to be flat. The graphene layer 120 is formed above the first region I and the second region II so as to partially, substantially or entirely prevent moisture from being absorbed onto the first region I and the second region II and make a noise reference of the sensing array formed in the first region I and the second region II be equal to each other. A function of the graphene layer 120 will be described in detail below.

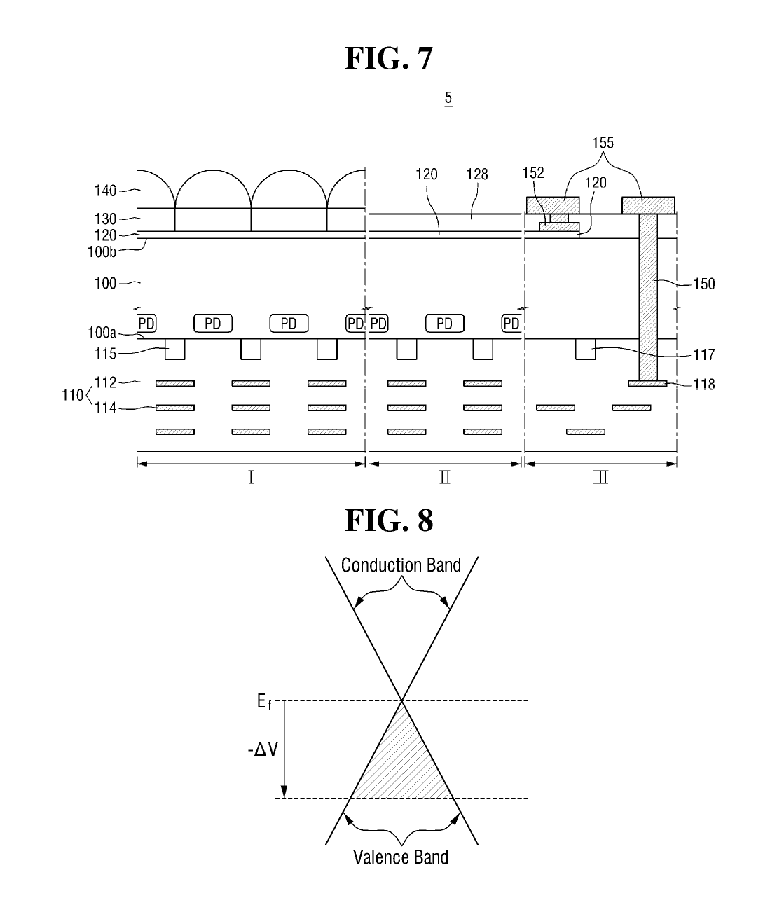

According to at least one example embodiment, the graphene layer 120 may include a monolayer graphene or a plurality of layers of graphenes (few-layer graphenes). The graphene layer 120 may be, for example, a p-type graphene layer or a neutral graphene layer which is neither n-type nor p-type. When the graphene layer 120 is a p-type graphene layer, the graphene layer 120 may include a doped p-type impurity. The p-type impurity may include oxygen (O) or gold (Au), but is not limited thereto. The graphene layer 120 may be electrically connected to a second metal wiring line (see reference numeral 118 in FIG. 7) and a description thereof will be made in detail with reference to FIG. 7.

In the image sensor 1 according to the first example embodiment, the graphene layer 120 may be formed to be in contact with the substrate 100, that is, the second surface 100b of the substrate. More specifically, the graphene layer 120 may be in direct contact with the substrate 100.

According to at least one example embodiment, the graphene layer 120 may be formed by attaching an already-made graphene layer onto the second surface 100b of the substrate, or can be directly formed on the substrate 100.

According to at least one example embodiment, the color filter 130 may be disposed above the graphene layer 120 in the first region I. The color filter 130 may be formed above the second surface 100b of the substrate and may be disposed between the graphene layer 120 and the microlens 140 which will be described below. That is, the graphene layer 120 may be formed between the color filter 130 and the second surface 100b of the substrate. The color filter 130 may include a red color filter, a green color filter, and a blue color filter.

According to at least one example embodiment, the microlens 140 is formed above the graphene layer 120 in the first region I. Specifically, the microlens 140 may be formed above the graphene layer 120 and the color filter 130 which are sequentially laminated on the second surface 100b of the substrate. The microlens 140 may be formed of an organic material such as a photosensitive resin or an inorganic material.

Even though not illustrated in FIG. 3, it is obvious that, above the graphene layer 120 which is formed in the second region II, various layers, such as a light blocking layer which blocks light from being incident into the second region II, may be further formed.

Hereinafter, an effect which may be obtained when the graphene layer 120 is used will be described.

First, according to at least one example embodiment, a surface of the graphene has hydrophobicity. Due to this property, in the image sensor 1 according to the first example embodiment, when the graphene layer 120 is formed on the second surface 100b of the substrate onto which light is incident, the graphene layer 120 blocks the moisture from being permeated into the substrate 100. Therefore, the graphene layer 120 may serve as an anti-moisture absorption layer of the image sensor.

Next, according to at least one example embodiment, the graphene layer 120 may have a very high translucency so that the light which passes through the color filter 130 may reach the photoelectric converting element PD but is hardly absorbed even when the light passes through the graphene layer 120. Therefore, when such a graphene layer 120 is used, a light quantity which reaches the photoelectric converting element is increased as compared with the anti-moisture absorption layer which has been used in the related art so that the signal to noise ratio (SNR) may be increased.

Next, according to at least one example embodiment, in the case of the p-type graphene layer 120, the graphene layer 120 may be used as a layer which reduces a dark current. For example, the p-type graphene layer 120 reduces the electron-hole pair which is thermally generated on the second surface 100b of the substrate so as to function as a pinning layer which reduces the dark current of the image sensor.

When the graphene layer 120 is formed as a p-type graphene layer, the above-described effect may be achieved.

According to at least one example embodiment, when a negative voltage is applied to the graphene layer 120, the graphene layer 120 may be changed into a p-type graphene layer. Specifically, the monolayer graphene has an energy band structure where a conduction band and a valence band meet. That is, an energy band gap of the monolayer graphene is substantially 0 eV. Therefore, if the negative voltage is applied to the monolayer graphene, the graphene of the monolayer is changed into the p-type graphene. Further, in the case of the plurality of layers of the graphenes, that is, few-layer graphenes, an energy band gap of the plurality of layers of the graphenes is very small, but is not 0 eV. Therefore, when the negative voltage is applied to the plurality of layers of graphenes, the plurality of layers of graphenes may be easily converted into a p-type. As a result, by applying the negative voltage to the graphene layer 120, the graphene layer 120 may be used as a layer which reduces a dark current. A method that applies the negative voltage to the graphene layer 120 will be described in detail with reference to FIG. 7.

According to at least one example embodiment, in the image sensor 1 according to the first example embodiment, it has been described that a layer which is disposed between the color filter 130 and the substrate 100 and is in contact with the second surface 100b of the substrate is the graphene layer 120. However, a layer which is disposed between the color filter 130 and the substrate 100 and is in contact with the second surface 100b of the substrate may also be a graphyne layer. Graphyne is an allotrope of carbon like graphene, but graphyne has a different structure from graphene. However, graphyne has an energy band structure which is similar to that of graphene, so that when the negative voltage is applied to graphyne, graphyne is changed into a p-type graphyne. Therefore, a graphyne layer may have a function which is similar to the graphene layer in the image sensor.

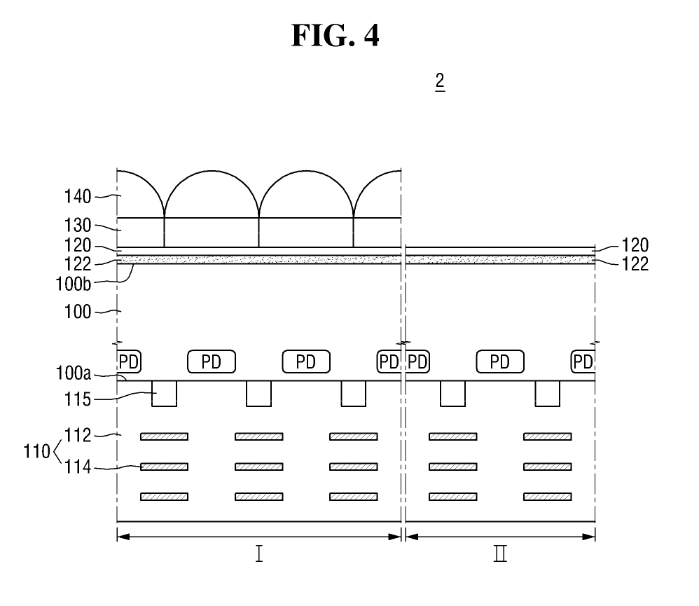

An image sensor according to a second example embodiment will be described with reference to FIG. 4. Hereinafter, different parts from the description with reference to FIG. 3 will be mainly described.

FIG. 4 is a diagram illustrating an image sensor according to a second example embodiment.

Referring to FIG. 4, the image sensor 2 according to the second example embodiment further includes a lower insulating layer 122 which may be formed in both the first region I and the second region II.

According to at least one example embodiment, the lower insulating layer 122 is disposed between a substrate 100 and a graphene layer 120. In the image sensor according to the second example embodiment, the graphene layer 120 is not in contact with a second surface 100b of the substrate. The lower insulating layer 122 may include an oxide insulating layer or a nitride insulating layer.

According to at least one example embodiment, the lower insulating layer 122 may be in contact with the graphene layer 120. That is, the graphene layer 120 may be formed to be in contact with the lower insulating layer 122. For example, the lower insulating layer 122 may include an oxide insulating layer. The lower insulating layer 122 is in contact with the graphene layer 120 so that oxygen included in the lower insulating layer 122 may be diffused into the graphene layer 120. The graphene layer 120 may be changed into the p-type graphene layer by oxygen which is diffused into the graphene layer 120.

According to at least one example embodiment, when the lower insulating layer 122 includes hafnium oxide (HfOx), the lower insulating layer 122 may reduce the dark current of the image sensor 2. Accordingly, by using the graphene layer 120 and the lower insulating layer 122 together, the dark current of the image sensor may be efficiently reduced. By doing this, the reliability of the image sensor may be improved.

According to at least one example embodiment, the graphene layer 120 may be electrically connected to a second metal wiring line (reference numeral 118 in FIG. 7) which is included in an insulating structure 110 formed above a first surface 100a of the substrate.

According to at least one example embodiment, the graphene layer 120 may serve as an anti-moisture absorption layer which partially, substantially or entirely prevents the moisture from being absorbed into the first region I and second region II.

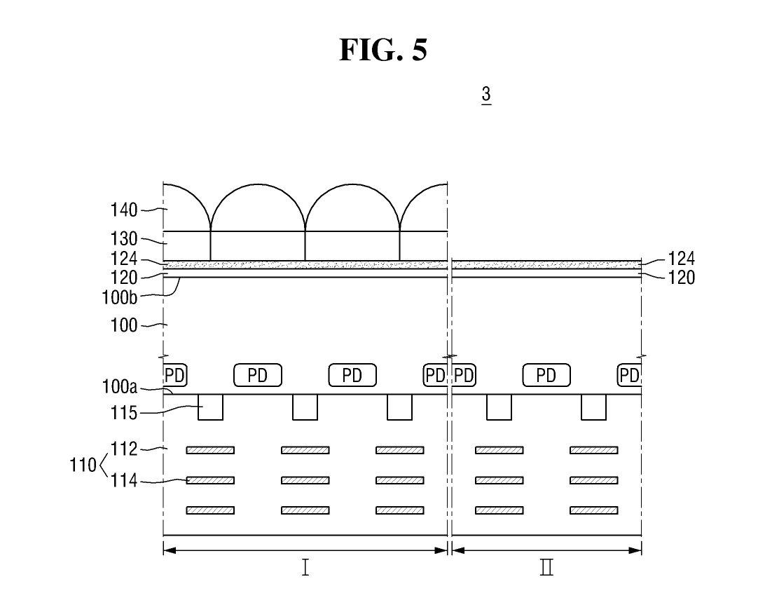

According to at least one example embodiment, an image sensor according to a third example embodiment will be described with reference to FIG. 5. Hereinafter, different parts from the description with reference to FIG. 3 will be mainly described.

FIG. 5 is a diagram illustrating an image sensor according to the third example embodiment.

Referring to FIG. 5, the image sensor 3 according to the third example embodiment further includes an upper insulating layer 124 which is formed in the first region I and the second region II.

According to at least one example embodiment, the upper insulating layer 124 is disposed between a graphene layer 120 and a color filter 130. Specifically, the upper insulating layer 124 is formed to be in contact with the graphene layer 120. The upper insulating layer 124 may include an oxide insulating layer or a nitride insulating layer.

For example, the upper insulating layer 124 may include an oxide insulating layer. The upper insulating layer 124 is in contact with the graphene layer 120 so that oxygen included in the upper insulating layer 124 may be diffused into the graphene layer 120. The graphene layer 120 may be changed into the p-type graphene layer by oxygen which is diffused into the graphene layer 120.

According to at least one example embodiment, the graphene layer 120 may be electrically connected to a second metal wiring line (reference numeral 118 in FIG. 7) which is included in the insulating structure 110 formed above a first surface 100a of the substrate.

According to at least one example embodiment, the graphene layer 120 may serve as an anti-moisture absorption layer which partially, substantially or entirely prevents the moisture from being absorbed into the first region I and second region II.

In the image sensor according to the third example embodiment, it is described that the graphene layer 120 is in contact with the second surface 100b of the substrate and the upper insulating layer 124, but example embodiments are not limited thereto.

According to at least one example embodiment, the image sensor 3 may further include the lower insulating layer 122 between the graphene layer 120 and the substrate 100, as described with reference to FIG. 4. Therefore, the lower insulating layer 122, the graphene layer 120, and the upper insulating layer 124 may be sequentially formed above the second surface 100b of the substrate.

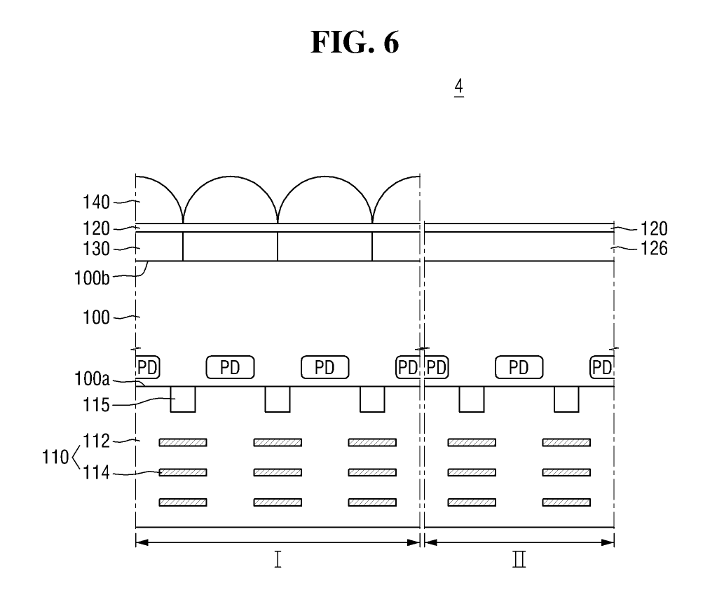

An image sensor according to a fourth example embodiment will be described with reference to FIG. 6. Hereinafter, different parts from the description with reference to FIG. 3 will be mainly described.

FIG. 6 is a diagram illustrating an image sensor according to the fourth example embodiment.

Referring to FIG. 6, the image sensor 4 according to the fourth example embodiment further includes a planarizing layer 126 which is formed in the second region II. Further, a graphene layer 120 in a first region I is disposed between a color filter 130 and a microlens 140 and the graphene layer 120 in the second region II is disposed on the planarizing layer 126. The planarizing layer 126 may include, for example, silicon oxide, but is not limited thereto.

According to at least one example embodiment, when there is a step between the first region I and the second region II, the graphene layer 120 may not be continuously formed over the first region I and the second region II. Therefore, in order to compensate the step caused by the color filter 120 formed in the first region I, the planarizing layer 126 may be formed in the second region II.

Even though not illustrated, if a light blocking layer which partially, substantially or entirely prevents the light from entering onto the second surface 100b of the substrate in the second region II is formed to have the same height as that of the color filter 130, the planarizing layer 126 may not be formed.

In FIG. 6, the color filter 130 and the planarizing layer 126 are formed between the graphene layer 120 and the second surface 100b of the substrate so that the graphene layer 120 may not reduce the dark current. However, the graphene layer 120 has hydrophobicity. Therefore, in the image sensor 4 according to the fourth example embodiment, the graphene layer 120 may serve as an anti-moisture absorption layer and also increase the signal to noise ratio (SNR).

An image sensor according to a fifth example embodiment will be described with reference to FIGS. 7 and 8. Hereinafter, different parts from the description with reference to FIG. 3 will be mainly described.

FIG. 7 is a diagram illustrating an image sensor according to the fifth example embodiment. FIG. 8 is a schematic diagram illustrating a conductivity change of a graphene in accordance with a voltage which is applied to a monolayer graphene in the monolayer graphene.

Referring to FIG. 7, the image sensor 5 according to the fifth example embodiment may include a first region I, a second region II, and a third region III. The image sensor 5 may further include a redistribution line 155 and a through-via 150 which are formed in the third region III.

According to at least one example embodiment, the first region I may be a sensing region, the second region II may be an OB region which is an optical black region, and the third region III may be a peripheral region. The third region III may be a peripheral region of the first region I and the second region II in which the sensing array 10 of FIG. 1 is formed.

According to at least one example embodiment, a first gate 115 may be disposed on the first surface 100a of the substrate corresponding to the first region I and the second region II and a second gate 117 may be disposed on the first surface 100a of the substrate corresponding to the third region III. Unlike the first gate 115, the second gate 117 may be a gate for operating the image sensor and transmitting and receiving a signal.

According to at least one example embodiment, an insulating structure 110 is formed not only in the first region I and the second region II, but also extends onto the first surface 100a of the substrate corresponding to the third region III. The insulating structure 110 includes not only a first metal wiring line 114 which is formed in the first region I and the second region II, but also, the second metal wiring line 118 which is formed in the third region III. The second metal wiring line 118 may include a plurality of wiring lines which is formed at the same level as a plurality of wiring lines which is included in the first metal wiring line 114.

According to at least one example embodiment, the graphene layer 120 is formed above a second surface 100b of the substrate. The graphene layer 120 may be formed on the entire first region I and second region II. Further, at least a part of the graphene layer 120 is formed to extend into the third region III. That is, the graphene layer 120 may overlap a part of the substrate 100 corresponding to the third region III. The graphene layer 120 which is formed over the first region I, the second region II, and the part of the third region III is formed to be flat.

According to at least one example embodiment, the graphene layer 120 is electrically connected to the second metal wiring line 118 which is included in the insulating structure 110. That is, a voltage may be applied to the graphene layer 120 through the second metal wiring line 118, which will be described below.

According to at least one example embodiment, a landing pad 152 may be formed on the graphene layer 120 which extends into the third region III. The landing pad 152 is electrically connected with the graphene layer 120. The landing pad 152 may include, for example, at least one of tungsten (W) and aluminum (Al), but is not limited thereto.

According to at least one example embodiment, a passivation layer 128 is formed above the second surface 100b of the substrate to cover the second region II and the third region III, but is not limited thereto. It is obvious that the passivation layer 128 may be formed above the microlens 140 which is formed in the first region I. The passivation layer 128 covers the graphene layer 120 and the landing pad 152. The passivation layer 128 may include, for example, silicon oxide, but is not limited thereto.

According to at least one example embodiment, the redistribution line 155 is formed above the second surface 100b of the substrate. The redistribution line 155 is formed on the passivation layer 128. In FIG. 7, it is illustrated that the redistribution line 155 is formed in the third region III for the convenience of description, but the redistribution line 155 may be formed in the second region II. The redistribution line 155 may be connected with the landing pad 152 via a contact which is formed in the passivation layer 128. The redistribution line 155 may include, for example, at least one of tungsten (W) and aluminum (Al), but is not limited thereto.

According to at least one example embodiment, the through via 150 is formed to penetrate the passivation layer 128, the substrate, and a part of the interlayer insulating layer 112. The through via 150 electrically connects the redistribution line 155 and the second metal wiring line 118. That is, the redistribution line 155 and the second metal wiring line 118 are connected via the through via 150. In FIG. 7, the through via 150 connects a wiring line of the second metal wiring line 118 which is the closest to the first surface 100a of the substrate with the redistribution line 155, but is not limited thereto.

According to at least one example embodiment, the voltage may be applied to the graphene layer 120 through the second metal wiring line 118, the through via 150, the redistribution line 155, and the landing pad 152. In the image sensor 5 according to the fifth example embodiment, in order to use the graphene layer 120 as a layer which may reduce the dark current, the graphene layer 120 may be a p-type graphene layer. Therefore, in order to create the graphene layer 120 as a p-type graphene layer, a negative voltage may be applied to the graphene layer 120 through a path described above.

Referring to FIGS. 7 and 8, the graphene has an energy band structure in which a conduction band and a valence band meet. That is, the graphene may be changed into an n-type graphene or a p-type graphene depending on whether to apply a positive voltage or negative voltage to the graphene.

That is, in order to change the graphene layer 120 into the p-type graphene layer, the negative voltage may be applied to the graphene layer 120. An energy band gap of the monolayer graphene is 0 eV so that when the negative voltage is applied to the graphene layer 120, the graphene layer is immediately changed into the p type graphene layer.

According to at least one example embodiment, in the case of a plurality of graphene layers which is formed by laminating several monolayer graphenes, the conduction band does not meet the valence band so that even though the negative voltage is applied to the graphene layer 120, the graphene layer 120 is not immediately changed into the p-type graphene layer. However, the energy band gap of the plurality of graphene layers is very small, so that the graphene layer 120 is easily changed into the p type graphene layer by applying the negative voltage to the graphene layer 120.

According to at least one example embodiment, the valence band and the conduction band of the graphene are changed with a linear gradient. That is, when the negative voltage is applied to the graphene, a hole concentration of the graphene varies in accordance with the negative voltage which is applied to the graphene (a portion represented by diagonal lines in FIG. 8). Therefore, the hole concentration of the graphene layer 120 may be adjusted by adjusting an amplitude of the negative voltage applied to the graphene layer 120. Even though the p type graphene layer 120 is used, the negative voltage is applied to the graphene layer 120 so that the hole concentration of the graphene layer 120 may be adjusted.

When the amplitude of the negative voltage which is applied to the graphene layer 120 is adjusted, the following advantages may be achieved, according to at least one example embodiment.

A layer which has a fixed hole concentration, or may be induced to have a fixed hole concentration, is used as a layer which reduces the dark current of the substrate 100. In this case, when a process element which may cause the dark current during a manufacturing process of an image sensor is increased, even though the layer which reduces the dark current is used, the dark current may exceed a tolerance range for the dark current of the image sensor. When the dark current exceeds the tolerance range for the dark current of the image sensor, the image sensor may not be used. That is, a yield of the image sensor may be lowered.

However, when the hole concentration of the graphene layer 120 is adjusted by adjusting the negative voltage which is applied to the graphene layer 120, the problem in that the yield of the image sensor is lowered may be solved. That is, if a process element which may cause the dark current during the manufacturing process of an image sensor is increased, the negative voltage which is applied to the graphene layer 120 is increased to increase the hole concentration of the graphene layer 120. Accordingly, the yield of the image sensor may be improved.

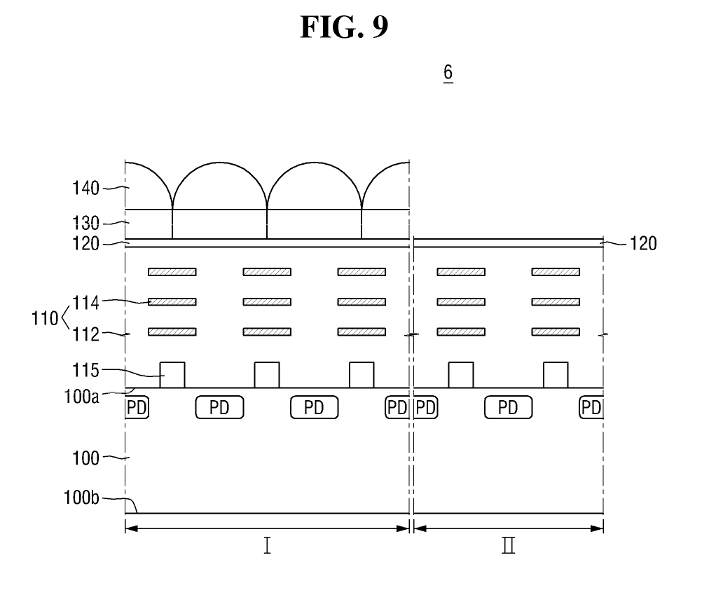

An image sensor according to a sixth example embodiment will be described with reference to FIG. 9. Hereinafter, different parts from the description with reference to FIG. 3 will be mainly described.

FIG. 9 is a diagram illustrating an image sensor according to the sixth example embodiment.

Referring to FIG. 9, the image sensor 6 according to the sixth example embodiment may include a graphene layer 120, an insulating structure 110, and a microlens 140.

According to at least one example embodiment, the graphene layer 120 is formed above a first surface 100a of the substrate. The graphene layer 120 is formed over the entire first region I and second region II. The graphene layer 120 is formed above the first surface 100a, that is, on the front side of the substrate, which is different from FIG. 3.

According to at least one example embodiment, the insulating structure 110 is formed above the first surface 100a of the substrate. The insulating structure 110 is disposed between the graphene layer 120 and the substrate 100.

In the image sensor according to the sixth example embodiment, the graphene layer 120 and the insulating structure 110 are formed above the same surface of the substrate, that is, above the first surface 100a of the substrate.

According to at least one example embodiment, a color filter 130 and the microlens 140 may be sequentially formed above the graphene layer 120 in the first region I. That is, the graphene layer 120 is disposed between the color filter 130 and the insulating structure 110.

In the image sensor 6 according to the sixth example embodiment, the graphene layer 120 may serve as an anti-moisture absorption layer and also increase the signal to noise ratio (SNR).

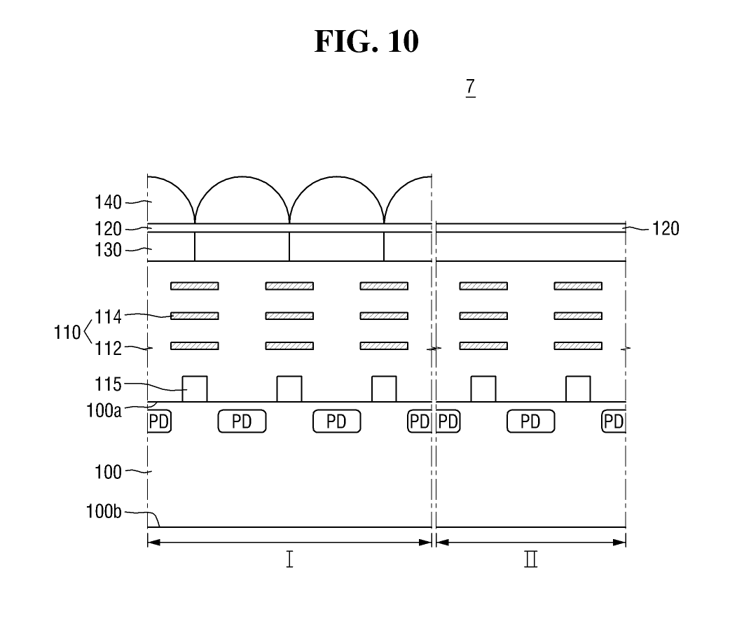

According to at least one example embodiment, an image sensor according to a seventh example embodiment will be described with reference to FIG. 10. Hereinafter, different parts from the description with reference to FIG. 9 will be mainly described.

FIG. 10 is a diagram illustrating an image sensor according to the seventh example embodiment.

Referring to FIG. 10, a graphene layer 120 is disposed between a microlens 140 and a color filter 130. Further, a planarizing layer 126 may be disposed between the graphene layer 120 of a second region II and an insulating structure 110 so as to form the graphene layer 120 in the second region II.

In the image sensor according to the seventh example embodiment, the graphene layer 120 may serve as an anti-moisture absorption layer. Further, a light quantity which reaches a photoelectric converting element PD is increased so that the graphene layer 120 may function to increase the signal to noise ratio (SNR).

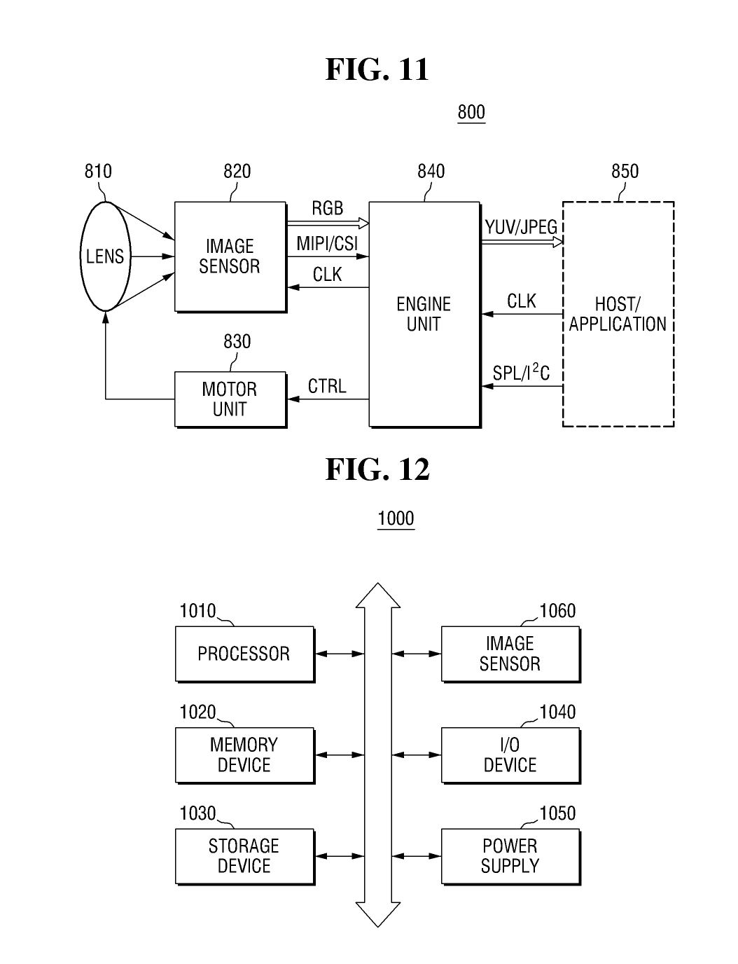

FIG. 11 is a block diagram illustrating an example in which an image sensor according to at least one example embodiment is applied to a digital camera.

Referring to FIG. 11, a digital camera 800 may include a lens 810, an image sensor 820, a motor unit 830, and an engine unit 840. The image sensor 820 may be an image sensor according to any one of the above-described first to seventh example embodiments.

According to at least one example embodiment, the lens 810 collects incident light into a light receiving region of the image sensor 820. The image sensor 820 may generate RGB data RGB having a Bayer pattern based on light which is incident through the lens 810. The image sensor 820 may provide RGB data RGB based on a clock signal CLK.

In some example embodiments, the image sensor 820 may interface with the engine unit 840 through a mobile industry processor interface MIPI and/or a camera serial interface CSI.

According to at least one example embodiment, the motor unit 830 adjusts a focus of the lens 810 or performs shuttering in response to a control signal CTRL received from the engine unit 840. The engine unit 840 controls the image sensor 820 and the motor unit 830. Further, the engine unit 840 may generate YUV data YUV which includes a brightness component, a difference between the brightness component and a blue component, and a difference between the brightness component and a red component or generate compressed data, for example, joint photography experts group (JPEG) data based on the RGB data received from the image sensor 820.

According to at least one example embodiment, the engine unit 840 may be connected to a host/application 850 and the engine unit 840 may provide the YUV data YUV or the JPEG data to the host/application 850 based on a master clock MCLK. Further, the engine unit 840 may interface with the host/application 850 through a serial peripheral interface (SPI) and/or an inter integrated circuit (I2C).

FIG. 12 is a block diagram illustrating an example in which an image sensor according to the example embodiments is applied to a computing system.

Referring to FIG. 12, a computing system 1000 includes a processor 1010, a memory device 1020, a storage device 1030, an I/O device 1040, a power supply 1050, and an image sensor 1060.

According to at least one example embodiment, the image sensor 1060 may be an image sensor according to any one of the above-described first to seventh example embodiments. Even though not illustrated in FIG. 12, the computing system 1000 may further include ports which may communicate with a video card, a sound card, a memory card, or a USB device or other electronic apparatuses.

According to at least one example embodiment, the processor 1010 may perform specific calculation or tasks. In some embodiments, the processor 1010 may be a micro-processor or a central processing unit (CPU).

According to at least one example embodiment, the processor 1010 may communicate with the memory device 1020, the storage device 1030, and the I/O device 1040 through an address bus, a control bus, and a data bus.

In some example embodiments, the processor 1010 may be connected to an extension bus such as a peripheral component interconnect (PCI) bus. The memory device 1020 may store data required for the operation of the computing system 1000.

For example, the memory device 1020 may be implemented as a DRAM, a mobile DRAM, an SRAM, a PRAM, a FRAM, a RRAM, and/or an MRAM. The storage device 1030 may include a solid state driver (SSD), a hard disk drive (HDD), or a CD-ROM.

The I/O device 1040 may include an input unit such as a keyboard, a keypad, or a mouse and an output unit such as a printer or a display. The power supply 1050 may supply an operating voltage required for the operation of the electronic apparatus 1000.

The image sensor 1060 is connected to the processor 1010 through the buses or another communication link to perform communication. As described, the image sensor 1060 compensates the offset for a reference voltage to generate precise image data. The image sensor 1060 may be integrated into one chip with the processor 1010 or into a separate chip from the processor 1010.

In the meantime, the computing system 1000 may be interpreted as all computing systems which use the image sensor. For example, the computing system 1000 may include a digital camera, a mobile phone, a personal digital assistant (PDA), a portable multimedia player (PMP), a smart phone, or a tablet PC.

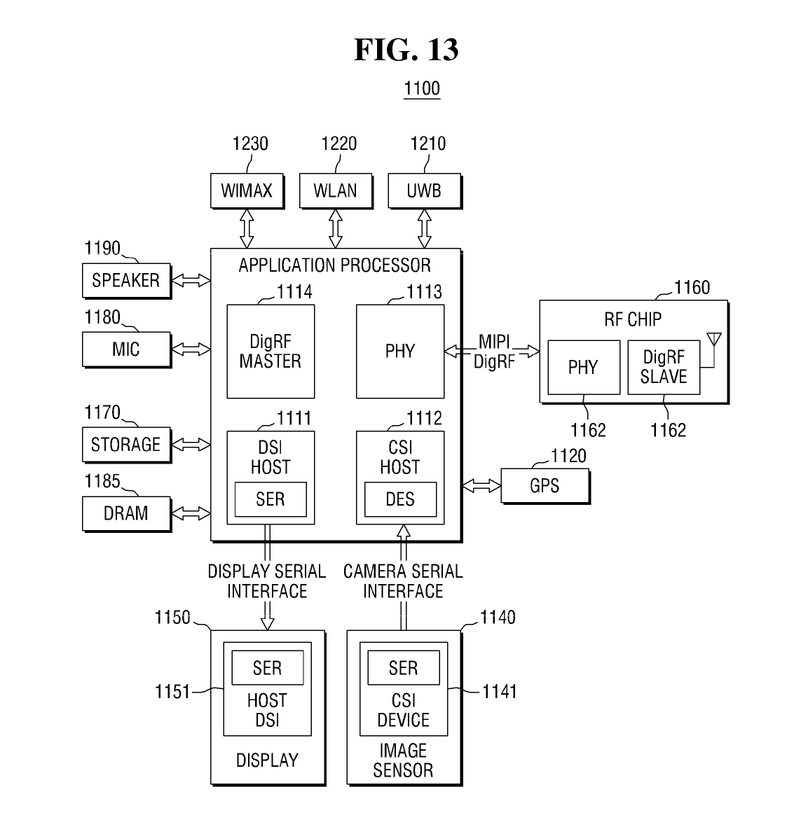

FIG. 13 is a block diagram illustrating an example of an interface which is used for the computing system of FIG. 12.

Referring to FIG. 13, the computing system 1100 may be implemented as a data processing device which uses or supports an MIPI interface and may include an application processor 1110, an image sensor 1140, and a display 1150.

A CSI host 1112 of the application processor 1110 may perform serial communication with a CSI device 1141 of the image sensor 1140 through a camera serial interface (CSI).

In one embodiment, the CSI host 1112 may include a deserializer DES and the CSI device 1141 may include a serializer SER. A DSI host 1111 of the application processor 1110 may perform serial communication with a DSI device 1151 of the display 1150 through a display serial interface (DSI). In one embodiment, the DSI host 1111 may include a serializer SER and the DSI device 1151 may include a deserializer DES. Moreover, the computing system 1100 may further include a radio frequency (RF) chip 1160 which may communicate with the application processor 1110. A PHY 1113 of the computing system 1100 and a PHY 1161 of the RF chip 1160 may transmit and receive data in accordance with a mobile industry processor interface (MIPI) DigRF.

Further, the application processor 1110 may further include a DigRF master DigRF MASTER 1114 which controls the data transmission and reception of the PHY 1161 in accordance with the MIPI DigRF. In the meantime, the computing system 1100 may include a global positioning system (GPS) 1120, a storage 1170, a microphone 1180, a dynamic random access memory (DRAM) 1185, and a speaker 1190. Further, the computing system 1100 may perform communication using an ultra wideband (UWB) 1210, a wireless local area network (WLAN) 1220, and a worldwide interoperability for microwave access (WIMAX) 1230. However, the structure and the interface of the computing system 1100 are one of examples, but are not limited thereto.

The foregoing is illustrative of the example embodiments and is not to be construed as limiting thereof. Although a few example embodiments have been described, those skilled in the art will readily appreciate that many modifications are possible in the example embodiments without materially departing from the novel teachings and advantages of the example embodiments. Accordingly, all such modifications are intended to be included within the scope of the example embodiments as defined in the claims. Therefore, it is to be understood that the foregoing is illustrative of example embodiments and is not to be construed as limited to the specific example embodiments disclosed, and that modifications to the disclosed example embodiments, as well as other example embodiments, are intended to be included within the scope of the appended claims. The example embodiments are defined by the following claims, with equivalents of the claims to be included therein.

What is claimed is:

1. An image sensor, comprising:
a substrate including a first surface and a second surface opposite the first surface and having a photoelectric converting element therein;
a graphene layer on the first surface of the substrate to be flat; and
a plurality of micro lenses on the graphene layer.

2. The image sensor of claim 1, further comprising:
an insulating structure including a metal wiring line on the second surface of the substrate; and
a color filter between the first surface of the substrate and the microlens,
wherein the graphene layer is between the color filter and the first surface of the substrate.

3. The image sensor of claim 2, wherein the graphene layer is in contact with the first surface of the substrate.

4. The image sensor of claim 2, further comprising:
a first oxide insulating layer between the graphene layer and the first surface of the substrate.

5. The image sensor of claim 4, wherein the first oxide insulating layer is in contact with the graphene layer.

6. The image sensor of claim 2, wherein the graphene layer and the metal wiring line are electrically connected through a through via which penetrates the substrate.

7. The image sensor of claim 1, further comprising:
an insulating structure including a metal wiring line on the second surface of the substrate, and a color filter between the first surface of the substrate and the microlens,
wherein the graphene layer is between the color filter and the microlens.

8. The image sensor of claim 1, wherein the graphene layer is a p-type graphene layer.

9. An image sensor, comprising:
a substrate having a first region and a second region and including a first surface and a second surface opposite the first surface, the second surface including a photoelectric converting element;
a carbon-based layer on the first surface extending over at least one of the first region and the second region; and
a plurality of micro lenses on the carbon-based layer.

10. The image sensor of claim 9, wherein the carbon-based layer is one of a graphene layer and a graphyne layer.

11. The image sensor of claim 9, wherein the plurality of micro lenses are on the carbon-based layer over the first region.

12. The image sensor of claim 9, wherein the carbon-based layer is configured to planarize the at least one of the first region and the second region.

13. The image sensor of claim 9, further comprising at least one insulating layer at least one of between the carbon-based layer and the substrate and between the carbon-based layer and the plurality of micro lenses.

14. The image sensor of claim 9, further comprising a color filter between the carbon-based layer and the plurality of micro lenses.

15. The image sensor of claim 9, further comprising an insulating structure at the second surface,
wherein the insulating structure comprises a metal wiring line.

16. The image sensor of claim 14, further comprising at least one insulating layer at least one of between the carbon-based layer and the substrate and between the carbon-based layer and the color filter.

17. The image sensor of claim 9, wherein:
the first region comprises a sensing region; and
the second region comprises an optical black region.

18. The image sensor of claim 9, further comprising a third region, wherein the carbon-based layer extends over at least a portion of the third region.

19. The image sensor of claim 9, further comprising a third region, wherein:
the carbon-based layer extends over at least a portion of the third region; and
the third region comprises a through-via through the carbon-based layer and the substrate, the through via connecting the carbon-based layer with the metal wiring line.

20. The image sensor of claim 13, wherein the at least one insulating layer comprises an oxide insulating layer.
